(19) United States
(12) Patent Application Publication
(10) Pub. No.: US 2024/0222506 A1
(43) Pub. Date: Jul. 4, 2024

(54) FIELD EFFECT TRANSISTOR COMPRISING TRANSITION METAL DICHALCOGENIDE (TMD) AND FERROELECTRIC MATERIAL

(71) Applicant: Intel Corporation, Santa Clara, CA (US)

(72) Inventors: Hojoon Ryu, Urbana, IL (US); Punyashloka Debashis, Hillsboro, OR (US); Rachel A. Steinhardt, Beaverton, OR (US); Kevin P. O'Brien, Portland, OR (US); John J. Plombon, Portland, OR (US); Dmitri Evgenievich Nikonov, Beaverton, OR (US); Ian Alexander Young, Olympia, WA (US)

(73) Assignee: Intel Corporation, Santa Clara, CA (US)

(21) Appl. No.: 18/148,871

(22) Filed: Dec. 30, 2022

(51) Int. Cl. H01L 29/78; H01L 21/02; H01L 21/8256; H01L 27/092; H01L 29/24; H01L 29/51; H01L 29/66; H01L 29/76

(52) U.S. Cl. CPC H01L 29/78391; H01L 21/02568; H01L 21/8256; H01L 27/092; H01L 29/24; H01L 29/516; H01L 29/66969; H01L 29/7606

(57) ABSTRACT

An apparatus, comprising a field effect transistor comprising a ferroelectric material, a channel material comprising a transition metal and a chalcogen, a source and a drain coupled to the channel material, the source and drain comprising a conductive material.

### BACKGROUND

Advanced nodes of complementary metal oxide semiconductor (CMOS)-related applications face challenges with respect to reducing power consumption and fabrication cost without sacrificing device performance. CMOS technology typically requires P-type and N-type channel material to produce a complementary circuit. Various implementations of this technology may utilize distinct materials for each channel type (e.g., one material for N-type, and a different material for P-type) or complicated doping techniques (e.g., ion implantation for silicon), which increases the cost and time of fabrication. CMOS circuits may also be susceptible to standby leakage, which may become more significant as transistor sizes are scaled down, especially in the case of silicon. Use of ferroelectric field effect transistors (FeFETs) may partially solve this issue, but standard ferroelectric materials (e.g., AlScN or doped HfO₂) may require high coercive voltages to switch dipoles and thus may not be suitable for power reduction.

### BRIEF DESCRIPTION OF THE DRAWINGS

FIG. 1 is a diagram of an example relationship between polarization and electrical field for the ferroelectric gate oxide of an N-type ferroelectric field effect transistor (FeFET).

FIG. 2 depicts example transfer curves of a negative capacitance field effect transistor (NCFET), a normal FET, and polarized FeFETs.

FIG. 3 is a flow diagram illustrating an example method of fabricating ferroelectric complementary metal-oxide-semiconductor (FeCMOS) devices.

FIGS. 4A-4I are top-down plan views of various example stages of manufacture of FeCMOS devices.

FIG. 5 is a cross-sectional view of example FeCMOS devices.

FIG. 6A is an example graph illustrating the relationship between drain current and drain voltage for the FeCMOS devices of FIG. 5.

FIG. 6B is an example graph illustrating the relationship between an input voltage and an output voltage for the FeCMOS devices of FIG. 5.

FIG. 7 is a cross-sectional view of an example P-type FET.

FIGS. 8A and 8B are example graphs of voltage and current relationships for the P-type FET of FIG. 7.

FIG. 9 is an example schematic of the FeCMOS devices of FIG. 41 and FIG. 5.

FIGS. 10A-10D illustrate example operating characteristics of the FeCMOS devices of FIG. 41 and FIG. 5.

FIG. 11 illustrates a mobile computing platform and a data server machine employing FeCMOS devices, in accordance with any of the embodiments disclosed herein.

FIG. 12 is a top view of a wafer and dies that may include FeCMOS devices, in accordance with any of the embodiments disclosed herein.

FIG. 13 is a cross-sectional side view of an integrated circuit device that may include FeCMOS devices, in accordance with any of the embodiments disclosed herein.

FIGS. 14A-14D are perspective views of example planar, FinFET, gate-all-around, and stacked gate-all-around transistors.

FIG. 15 is a cross-sectional side view of an integrated circuit device assembly that may include FeCMOS devices, in accordance with any of the embodiments disclosed herein.

FIG. 16 is a block diagram of an example electrical device that may include FeCMOS devices, in accordance with any of the embodiments disclosed herein.

### DETAILED DESCRIPTION

Various embodiments herein include a ferroelectric field effect transistor (FeFET) with a channel material comprising a 2D transition metal dichalcogenide (TMD). A TMD may be a semiconductor of type MC₂, with M being a transition metal (e.g., Mo or W) and C being a chalcogen (e.g., S, Se, or Te). For example, the channel material may comprise WSe₂, MoS₂, MoTe₂, WS₂, or the like. In various embodiments, the 2D TMD may utilize the large wafer scale and/or be grown by chemical vapor deposition (CVD) or metal organic chemical vapor deposition (MOCVD) techniques. TMD exhibiting atomic-scale thickness may be referred to as 2D TMD or mono-layer TMD. In some embodiments, the channel material may be a mono-layer TMD (e.g., only one layer of the constituent atoms of the material) or a multi-layer TMD (e.g., including up to a few tens of layers of the constituent atoms of the material).

Contrary to conventional silicon, further channel dimension scaling of transistors is feasible with 2D TMD without materially sacrificing mobility. Also, usage of 2D TMD enables relatively easy channel polarity tuning (simple chemical doping or ferroelectric dipole switching makes it possible to form P-type and N-type channels from the same monolayer TMD), eliminating the need for a complicated doping method such as ion implantation or external field biasing to tune the channel. For example, in some embodiments, a 2D TMD having ambipolar behavior may be used as a channel material and the polarity (e.g., P-type or N-type) of the channel may be reversible through ferroelectric dipole induced doping to the 2D TMD.

In various embodiments, the ferroelectric material of the device may comprise a low power and high-speed switching ferroelectric material that provides non-volatility and reduces energy consumption. In some embodiments, the ferroelectric material of the device comprises perovskite ferroelectric BaTiO₃ (BTO), which may reduce the switching voltage and improve the switching speed of the device considerably. For example, epitaxially grown BTO material may exhibit ferroelectric dipole switching with ultra low voltage (e.g., <100 mV) and low coercive field (Ec) (e.g., <10 kV/cm). The Ec of BTO is much lower than that of standard ferroelectric materials, such as doped HfO₂ (Ec ˜1-2 MV/cm) and AlScN (Ec ˜2-6 MV/cm). In various embodiments, the low Ec of BTO may enable FeFET operation with ultra-low energy consumption. As another example, high-quality BTO may enable switching speeds (tₛ) around the sub-nanosecond range with thickness and area scaling (e.g., much faster than an organic polymer, polyvinylidene fluoride (PVDF), or 2D ferroelectric material such as CuInP₂S₆ or In₂Se₃). In other embodiments, the ferroelectric material of the device comprises another perovskite ferroelectric material such as BiFeO₃, LaₓBi₁₋ₓFeO₃, or BaₓSr₁₋ₓTiO₃ or a superlattice of a ferroelectric and a dielectric material, e.g., [SrTiO₃/PbTiO₃]ₙ.

A combination of a ferroelectric material (e.g., BTO) and 2D TMD channel material may realize both non-volatility and easy tunability of the channel. In various embodiments, the non-volatile FeFETs may be reconfigurable and may be used as non-volatile logic and/or memory. In various embodiments, the devices may be used to make low power CMOS circuits with fast operating speeds, such as multi-functional electronics (e.g., logic-in-memory devices).

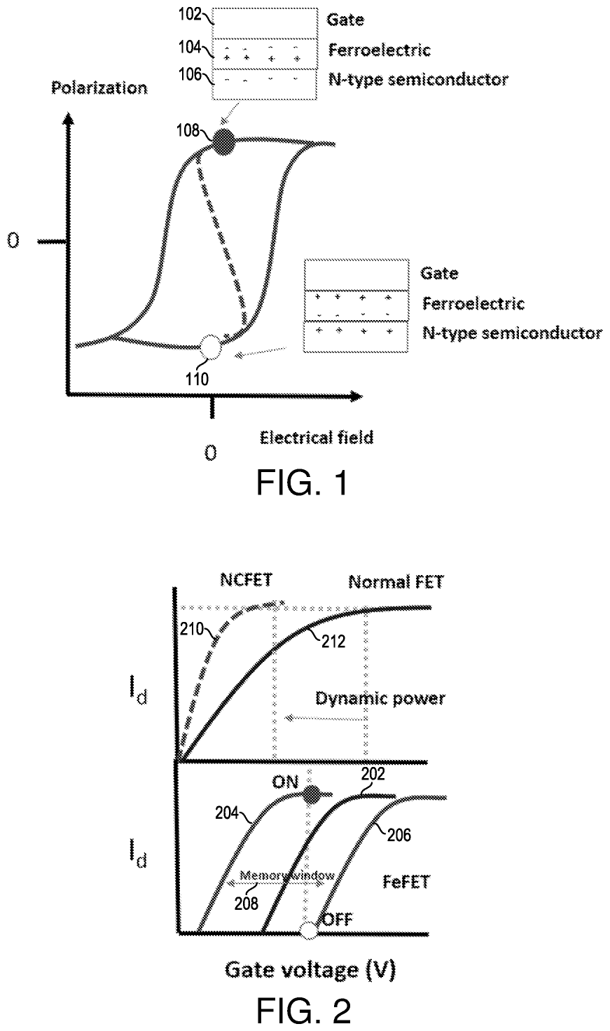

FIG. 1 is a diagram of an example relationship between polarization and electrical field for the ferroelectric gate oxide an N-type ferroelectric field effect transistor (FeFET). As depicted, the FeFET may include (among other elements) a gate material 102, a ferroelectric material 104 (e.g., comprising BTO or other suitable ferroelectric material), and a semiconductor material 106 (e.g., comprising 2D TMD or other suitable semiconductor material), which is an N-type semiconductor material in the depicted embodiment. In the FeFET structure, the conventional dielectric oxide material that would be formed between the gate material and the semiconductor material of the channel in a standard FET is replaced by the ferroelectric material 104.

In general, ferroelectricity refers to the material property of having spontaneous polarization and reversible switching under an applied electrical field. The polarization induced by the ferroelectric dipole is retained even after external power is cut off and the external electrical field is zero, as shown in FIG. 1.

When a positive pulse that is larger than the coercive voltage of the ferroelectric material 104 is applied to the gate material 102, the polarized charge in the ferroelectric material is aligned downward such that the positive side will be on the bottom of the ferroelectric material and will face the semiconductor material 106 forming the channel. This polarization attracts electrons at the interface between the ferroelectric material 104 and channel region formed by the semiconductor material 106, which will vary the channel conductance (since the conductance depends on the charge accumulation/depletion in the channel). This will lead to a threshold voltage reduction in the channel. The solid circle 108 corresponds to the ON state of the N-type FeFET.

Conversely, when a negative pulse is applied to the gate material 102, the polarized charge in the ferroelectric material may be aligned upward such that the positive side will be on the top of the ferroelectric material and will face the gate material 102 and the negative side will be on the bottom of the ferroelectric material facing the semiconductor material 106 forming the channel. This polarization depletes electrons at the interface between the ferroelectric material 104 and channel region formed by the semiconductor material 106, which again will vary the channel conductance. This will result in a threshold voltage increase. The empty circle 110 corresponds to the OFF state of the N-type FeFET.

When a gate voltage is applied to the FeFET stack (e.g., 102, 104, 106), the voltage is divided across the ferroelectric material 104 and the semiconductor material 106. A portion of the gate voltage may drop across the ferroelectric material 104 and another portion may drop across the semiconductor material 106. When the semiconductor material 106 is a very thin layer (e.g., a mono-layer 2D TMD), minimal voltage is dropped across the semiconductor material 106, resulting in a reduction in the voltage that needs to be applied across the ferroelectric material 104 (relative to other semiconductor materials) to induce the desired behavior of the FeFET.

FIG. 2 depicts example transfer curves of a negative capacitance field effect transistor (NCFET) (which may be considered a type of FeFET), a normal FET, and polarized FeFETs. The bottom portion of FIG. 2 shows a waveform 202 of drain current as a function of gate voltage for a normal FET (e.g., a FET with a dielectric oxide rather than a ferroelectric material). As described above, the conductance variation in a FeFET can lead to a threshold voltage shift (Vₜₕ) and can alter the drain current flowing through the channel for a given applied gate voltage. This alteration (based on the specific polarization) may take the form of two different states corresponding to the ON and OFF state. Waveform 204 corresponds to the ON state (e.g., the result of the positive gate voltage case described above) and waveform 206 corresponds to the OFF state of the FeFET (e.g., the result of the negative gate voltage case described above). As illustrated, the threshold voltage of the ON state is lower than the threshold voltage of the normal FET, while the threshold voltage of the OFF state is higher than the threshold voltage of the normal FET.

In various embodiments, bit information (e.g., ‘0’ and ‘1’ values) may be assigned to the ON/OFF states, wherein a determination of the particular state of the FeFET allows determination of the bit value for the FeFET. Thus, the FeFET may be utilized as a binary bit memory cell. The states may be distinguished, e.g., by using a read voltage that is within a memory window voltage range 208 (e.g., between the Vₜₕ of the ON state and the Vₜₕ of the OFF state). Because ferroelectricity is non-volatile, the data stored by the FeFET can be maintained, even when the external power is turned off. Thus, the ON and OFF states are non-volatile states because the polarization of the FeFET is maintained once the FeFET has been written to (e.g., via application of a gate voltage).

In various embodiments, the stack of the FeFET described above (or elsewhere herein) may be modified with the inclusion of a dielectric material with the ferroelectric material (e.g., 104) to form a negative capacitance FET (NCFET). For example, a dielectric material may be placed between the ferroelectric material and the channel material or the ferroelectric material may be placed in between the dielectric material and the channel material. As another example, a superlattice of a ferroelectric material and a dielectric material may be used, e.g., [SrTiO₃/PbTiO₃]ₙ. The structure of the NCFET can have an effective negative capacitance on its gate node. The NCFET may operate as a steep slope switching transistor with low power. A waveform 210 corresponding to the NCFET and a waveform 212 corresponding to a normal FET is shown in the upper portion of FIG. 2. As depicted, the NCFET has a sharper subthreshold slope than the normal FET. In a normal FET, the lower limit of subthreshold swing (S.S) value may be around 60 mV/dec at room temperature. However, negative capacitance by ferroelectric switching in the NCFET may reduce the S.S below 60 mV/dec. The FeFET may also be thought of as a steep slope transistor because the voltage required to turn the transistor on and off is close to the coercive voltage of the ferroelectric material (in some embodiments, this voltage may be as low as ˜100 mV), resulting in power savings.

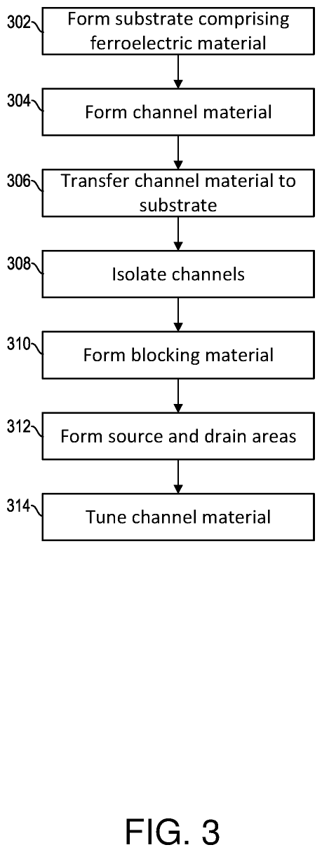

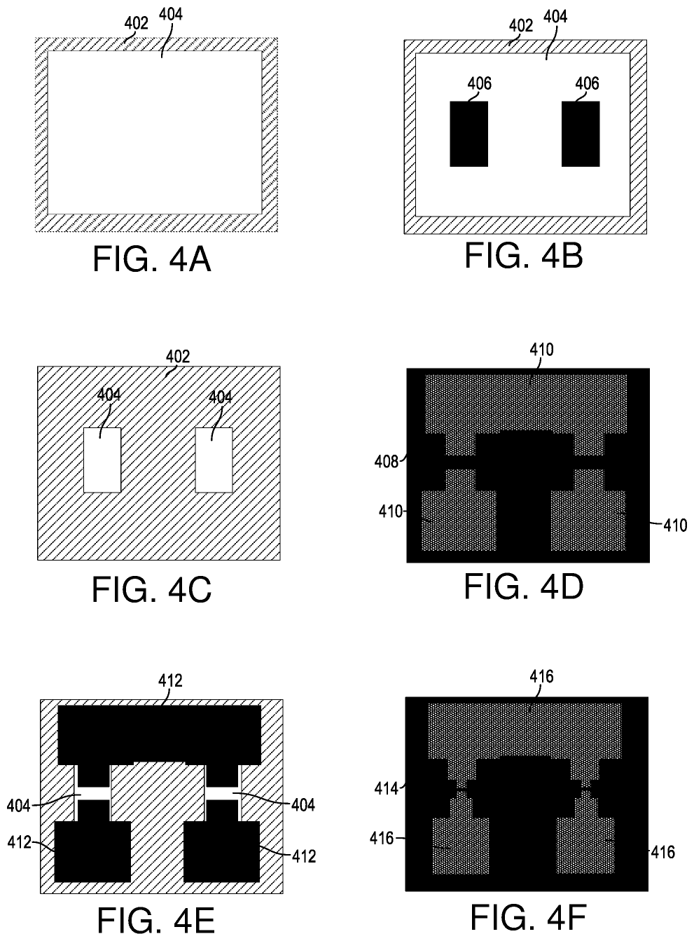

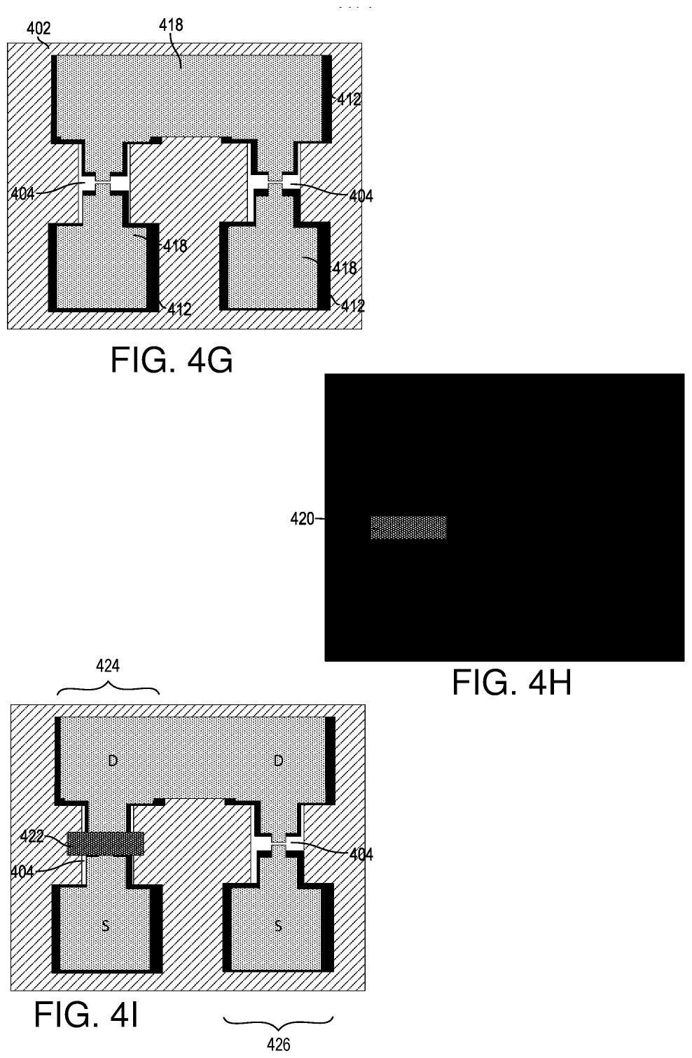

FIG. 3 is a flow diagram illustrating an example method of fabricating ferroelectric complementary metal-oxide-semiconductor (FeCMOS) devices (e.g., FeFETs). The method will be described in connection with FIGS. 4A-4I, which are top-down plan views of various example stages of manufacture of FeCMOS devices. Any suitable modifications of the method are contemplated herein, including omission, addition, or modification of operations.

At 302, a substrate comprising a ferroelectric material is formed. In some embodiments, the ferroelectric material of the substrate predominately, substantially, or primarily comprises BaTiO₃ (BTO), such as perovskite ferroelectric BTO. In some embodiments, the BTO may be epitaxially-grown BTO. In various embodiments, the ferroelectric material (e.g., BTO) is grown on top of a conductive material (e.g., metal) that is lattice matched to the ferroelectric material. In various embodiments, the conductive material may be formed on top of an insulating material.

At 304, a channel material is formed. The channel material may be a semiconductor. In various embodiments, the channel material predominately, substantially, or primarily comprises a transition metal and a chalcogen. In some embodiments, the channel material may comprise a 2D TMD film formed using wafer scale MOCVD or other suitable techniques. For example, the 2D TMD film may be formed on top of a second substrate (e.g., of a wafer) primarily comprising SiO₂ or Si. In some embodiments, the 2D TMD film is a single atomic layer, although other embodiments contemplate other suitable thicknesses.

At 306, the channel material is transferred onto the substrate. In various embodiments, a surface treatment is first applied to the substrate (e.g., to the ferroelectric material or a portion thereof) of the substrate and then the channel material is placed on top of (or otherwise in contact with) the ferroelectric material. In one embodiment, the surface treatment may include a rapid thermal annealing at an elevated temperature in the presence of oxygen (O₂). The surface treatment may result in improved yield relative to transfer without the surface treatment. In various embodiments, a dry method is used to transfer the 2D film from the substrate of the wafer on which it was grown to the substrate comprising the ferroelectric material. FIG. 4A depicts a channel material 404 placed on top of a substrate comprising a ferroelectric material 402.

At 308, channels are isolated. The channels for the FeCMOS devices may be formed from portions of the channel material. In one embodiment, the channels may be isolated by applying a hard mask material over portions of the channel material to pattern the channel(s) and then removing the other portions of the channel material. In some embodiments, optical or e-beam lithography may be used to pattern the channel and a dry etching technique such as reactive ion etching (e.g., using O₂ plasma) may be used to remove the non-channel part of the channel material. FIG. 4B depicts a mask material 406 formed over the channel material 404 in the desired area for the channels. FIG. 4C depicts the remaining channel material 404 (e.g., the portions that were underneath the mask material 406) over the ferroelectric material 402 after the non-channel portions have been removed.

At 310 a blocking material is formed. The blocking material may reduce the vertical gate leakage from the relatively large source/drain pad contact region of the FeFETs. In various embodiments, the blocking material may predominately, substantially, or primarily comprise an oxide (e.g., SiO₂). In a particular embodiment, the blocking material is about 20 nm thick, although other embodiments may utilize blocking materials of any suitable thicknesses.

In various embodiments, a liftoff process may be used to form the blocking material. In such a process, a sacrificial material (e.g., a photoresist) is formed over the substrate (e.g., over the ferroelectric material 402 and the remaining channel material 404), the sacrificial material is patterned (e.g., by etching the desired pattern), the target material (in this case the blocking material) is deposited, and the remaining sacrificial material (along with the target material on top of the sacrificial material) is removed (e.g., with a chemical etch), leaving the blocking material in the desired pattern.

FIG. 4D illustrates a sacrificial material 408 and patterned areas 410 (e.g., formed by removing the sacrificial material prior to deposition of the target material). FIG. 4E illustrates the resulting blocking material 412 after the deposition of the blocking material (e.g., SiO₂) and removal of the sacrificial material 408. The blocking material 412 forms an isolation layer with respective openings for the channels (these openings will form the channel lengths).

At 312, source and drain areas are formed. In various embodiments, the source and drain areas may be formed via a liftoff process. In various embodiments, the source and drain areas may be formed by depositing any suitable electrically conductive material, such as one or more metals. In a particular embodiment, the source and drain areas are formed by depositing Ru and Au. Thus, in some embodiments, the conductive material may predominately, substantially, or primarily comprise Ru and Au.

FIG. 4F illustrates a sacrificial material 414 and patterned areas 416 (e.g., formed by removing the sacrificial material prior to deposition of the target material for the sources and drains). FIG. 4G illustrates the resulting conductive material 418 after the deposition of the conductive material and removal of the sacrificial material 414. The conductive material 418 may form metal pads for the sources (S) and drains (D) of the FeCMOS devices. These metal pads are isolated from the material underneath (e.g., ferroelectric material 402) by the blocking material 412, but are in contact with the channel material 404, thus forming source and drain areas.

At 314, the channel material is tuned. For example, when formed initially, the channel material may have characteristics of a certain channel type (e.g., P-type) and then may be tuned to another type (e.g., N-type). An N-type channel may use electron flow as the charge carrier, whereas a P-type channel may use hole flow as the charge carrier. In the embodiment depicted in FIGS. 4H and 4I, the tuning includes patterning an area 420 for deposition of an oxide material 422 on one of the channel material 404 areas, for the channel which will later serve as an N-type region. In some embodiments, the patterning may be performed as part of a liftoff process. The oxide material may result in interfacial dipoles (inducing electrostatic doping due to dipoles). In an embodiment, the oxide material predominately, substantially, or primarily comprises Al and O (e.g., Al₂O₃). In another embodiment, the oxide material may predominately, substantially, or primarily comprise W and O (e.g., WOₓ) (e.g., this material may cause a WSe₂ channel material to behave as a P-type channel). The thickness range for the oxide materials used for channel tuning may be relatively large (e.g., between a mono-layer (e.g., ˜0.3 nm thick) to several tens of nm or other suitable thickness).

After the deposition, the channel material covered by the oxide may be tuned from a P-type to N-type channel (or vice-versa). Thus, after the channel tuning, the process results in N-type transistors (e.g., N-type FET 424) and a P-type transistors (e.g., P-type FET 426) which have respective sources (S) and drains (D), where the drains of the two transistors are coupled together in the depicted embodiment.

In alternative embodiments, instead of using the same material (e.g., 2D TMD) for the channel material of both types of FETs and then tuning FETs from one type to the other, different channel materials may be used (e.g., a first material for N-type FETs and a second material for P-type FETs).

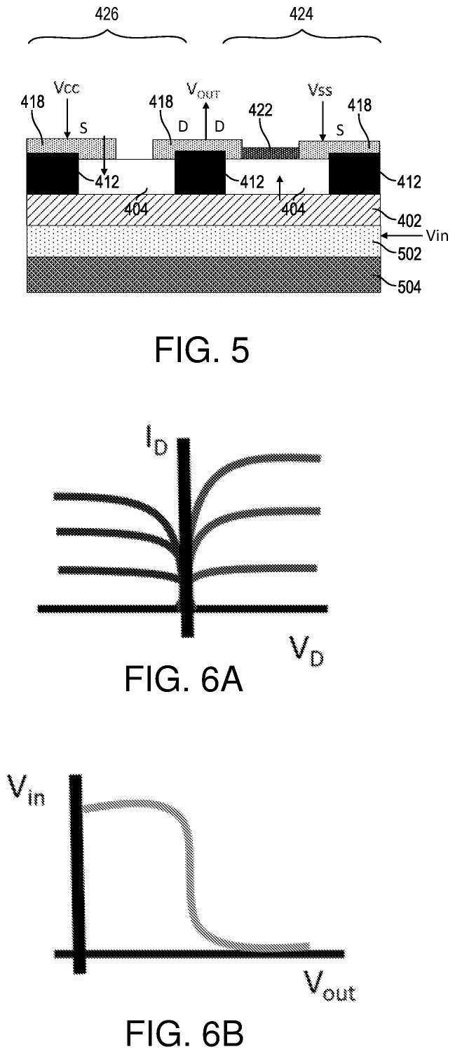

FIG. 5 is a cross-sectional view of example FeCMOS devices (e.g., N-type FET 424 and P-type FET 426). This view corresponds to the FeCMOS devices shown in FIG. 41. In this embodiment, the devices are coupled together to form an inverter circuit.

FIG. 5 depicts the ferroelectric material 402, channel material 404, blocking material 412, conductive material 418, and oxide material 422. FIG. 5 also depicts conductive layer 502 and insulating layer 504 underneath the ferroelectric material 402 (e.g., these layers may be part of the substrate onto which the channel material is transferred at 306). The conductive layer 502 may operate as a gate electrode for one or more FeCMOS devices. In one embodiment, the conductive layer 502 predominately, substantially, or primarily comprises SrRuO₃ (SRO). In some embodiments, the insulating layer 504 may predominately, substantially, or primarily comprise SiSrTiO₃ (SiSTO) (e.g., which may be formed by growing STO on top of a Si wafer) or DyScO₃ (DSO). In various embodiments, the lattice parameters of the conductive layer 502 are matched to the lattice parameters of the ferroelectric material 402 and insulating layer 504. In various embodiments, the three bottom layers 504, 502, and 402 may be grown together in one chamber (e.g., during 302). In various embodiments, the conductive material 502 may correspond to gate 102, the ferroelectric material 402 may correspond to ferroelectric 104, and/or the channel material 404 underneath the oxide material 422 may correspond to the N-type semiconductor 106.

In this embodiment, the source and drain areas may operate as Schottky contacts without doped regions underneath (contrary to many other CMOS FETs). Rather, a single doped channel is used, and the source and drain each form Schottky junctions.

FIG. 6A is an example graph illustrating the relationship between drain current and drain voltage for the FeCMOS devices of FIG. 5. As long as the gate voltage is kept within the memory window (e.g., as depicted in FIG. 2), the FeFETs 424 and 426 may operate in a manner similar to a standard MOSFET with a high-k dielectric. Curves for the N-Type FET 424 are shown on the right and curves for the P-Type FET 426 are shown on the left (with each curve corresponding to a different gate voltage).

FIG. 6B is an example graph illustrating the relationship between an input voltage and an output voltage for the FeCMOS devices of FIG. 5. In this embodiment, the FeCMOS devices are coupled together in an inverter circuit. As shown in FIG. 5, the source of the P-Type FeFET 426 is coupled to Vcc, the source of the N-Type FeFET 424 is coupled to Vss, the drains of the FeFETs 424 and 426 are coupled together and to Vout, and the gates (formed by conductive layer 502) of the FeFETs 424 and 426 are coupled together and to Vin. As expected, the graph shows a high Vout for a low Vin and a low Vout for a high Vin.

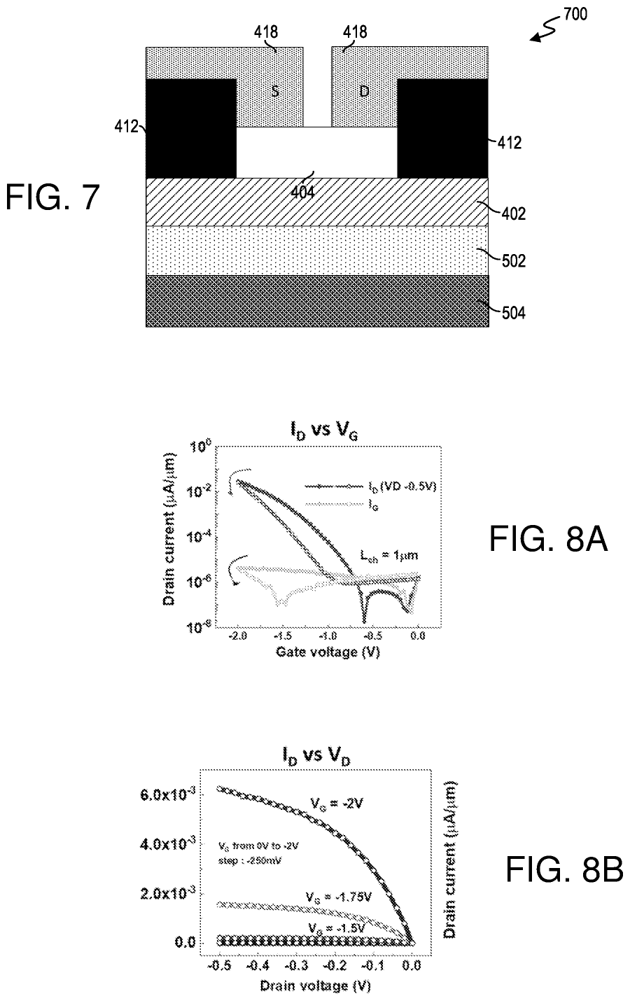

FIG. 7 is a cross-sectional view of an example P-type FET 700 which may be manufactured according to any of the methods described herein. The P-type FET 700 is formed of some of the same materials used to form the P-type FeFET 426.

FIGS. 8A and 8B are example graphs of voltage and current relationships for the P-type FET of FIG. 7. These graphs are based on use of SiSTO for the insulating layer 504, SRO for the conductive layer 502, non-ferroelectric BTO instead of the ferroelectric material 402, WSe₂ for the channel material 404, and SiO₂ for the blocking material 412.

The Id vs. Vg and Id vs. Vd curves in FIGS. 8A and 8B demonstrate how a monolayer WSe₂ and non-ferroelectric BTO combination work as a P-type FET. To generate the graphs, the gate voltage was double swept from 0 to −2V, with a −0.5V drain voltage. The FeFET 700 shows a sizable I_{ON}/I_{OFF} ratio (>104) and a low gate leakage current, thus indicating operation as a FET. In the experimental structure that formed the basis for the graphs, the WSe₂ was not lattice matched with the BTO (and improved performance would be expected from lattice matched WSe₂). By choosing the deposition conditions of BTO to make it a ferroelectric material, a FeFET may be realized by the structure shown in FIG. 7.

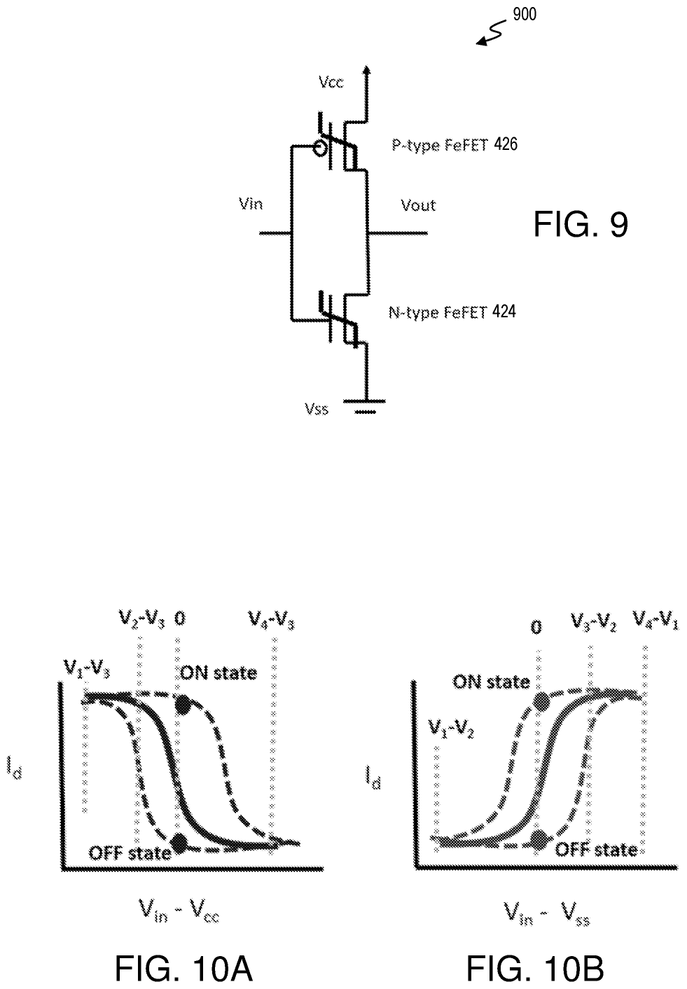

FIG. 9 is an example schematic of the FeCMOS devices of FIG. 41 and FIG. 5. As described above, during the fabrication process, a channel material can be tuned through simple oxide layer deposition on the channel material (e.g., N-type WSe₂ may be formed from P-type WSe₂). A CMOS circuit may be formed by combining transistors having both types of channels. The input bias applied may determine whether ferroelectric switching is generated or not in the ferroelectric material. Thus, depending on the bias conditions, the CMOS circuit can harness the ferroelectric memory hysteresis, steep slope switching, or normal switching behavior.

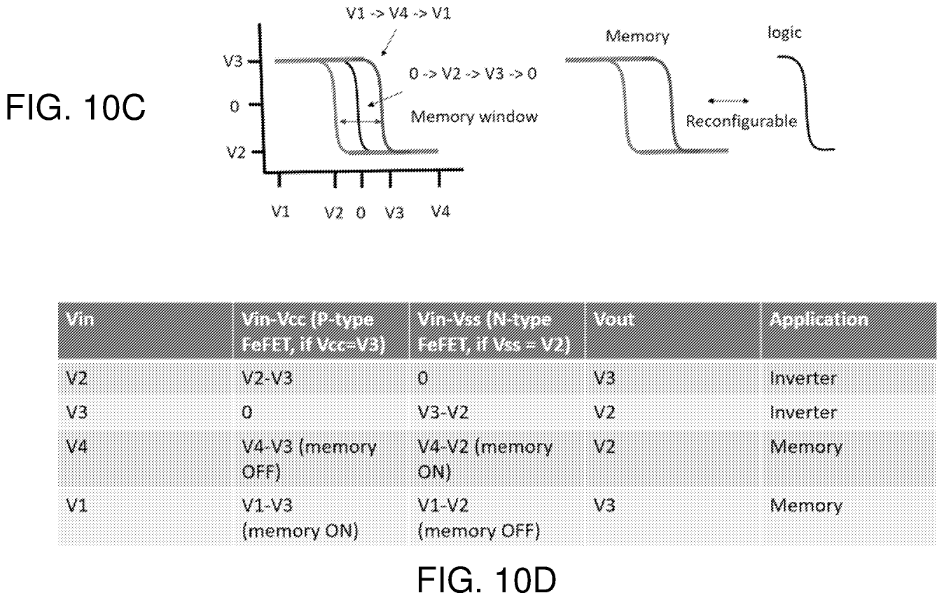

FIGS. 10A and 10B respectively show the transfer curves of P-type FeFET 426 and N-type FeFET 424 (when operating normally and when polarized to ON and OFF states) while FIG. 10C shows operation of the combined circuit as an inverter. Different voltage levels (e.g., V4>V3>0>V2>V1) may be used to operate the circuit 900 according to a desired function. During operation, Vdd and Vss are set to appropriate voltages to enable a non-destructive read process. The x-axis of the graph is the gate voltage (Vin-Vcc for the P-type FeFET, and Vin-Vss for the N-type FeFET) and the y-axis is the drain current. V2 and V3 may be equivalent to Vss and Vcc in some situations.

When the circuit 900 is operated as a conventional CMOS inverter (as depicted by the first two rows of the table in FIG. 10D), V2 or V3 may be used as input for Vin. When the gate voltages of the FETs (Vin-Vcc for the P-type FeFET, and Vin-Vss for the N-type FeFET) are smaller than the respective coercive voltages, both FeFETs operate as conventional FETs without exhibiting memory effects. Thus, the circuit 900 will operate as a standard CMOS inverter. When V2 is input, the circuit 900 will output V3, and when V3 is input, the circuit 900 will output V2. This operation is depicted in the first two rows of FIG. 10D.

In order to operate the circuit 900 as a ferroelectric memory inverter (as depicted by the last two rows of the table in FIG. 10D), Vin may be biased to cause the circuit 900 to exhibit non-volatile memory behavior. For example, if V4 is applied as input, the applied bias will exceed the coercive voltage of the N-type FeFET 424. This will increase the N-channel conductance through ferroelectric polarization, which results in the FeFET 424 entering the memorized ON state. Concurrently, the applied bias will cause the P-type FeFET 426 to enter an OFF state. Accordingly, the output voltage Vout is driven to V2 (representative of a “low” state).

In contrast, when V1 is applied as input, the applied bias will exceed the coercive voltage of the P-type FeFET 426, resulting in the FeFET 426 entering the ON state. Concurrently, the applied bias will cause the N-type FeFET 424 to enter the OFF state. Thus, Vout will change to V3 (representative of a “high” state).

The ON and OFF states of the FeFETS are obtained through ferroelectric switching and these states are non-volatile. Therefore, the circuit 900 may retain its output status even after external power is turned off. The state of the circuit 900 may be read by applying a voltage within the memory window depicted in FIG. 10C.

In alternative embodiments, NCFET manufacturing techniques may be performed to form the FeFETS of circuit 900. For example, an additional oxide material may be included with the ferroelectric material (e.g., as described above). The resulting reduced dynamic power of the FeFETs will realize additional energy benefits, and the steep slope switching will help decrease the delay incurred in turning the FeFETs ON and OFF.

As should be apparent, the FeFETs may be manufactured in any suitable arrangement (and are not limited to the inverter configuration shown in FIGS. 4I and 5). For example, the FeFETs may be used to form any suitable logic and/or memory circuits. In one embodiment, the FeFETS may be used to form reconfigurable logic gates and memory in a field programmable gate array (FPGA). The methods described herein (e.g., with respect to FIG. 3) may be used to concurrently form any suitable number of FeFETs for an integrated circuit.

Any of the FeFETs described above may be implemented in any integrated circuit of any IC die. Such an IC die may include logic and/or memory, for example. The IC die may include both logic and memory. The FeFETs described above may be implemented only within logic circuitry, only within memory array circuitry, or within both logic circuitry and memory array circuitry.

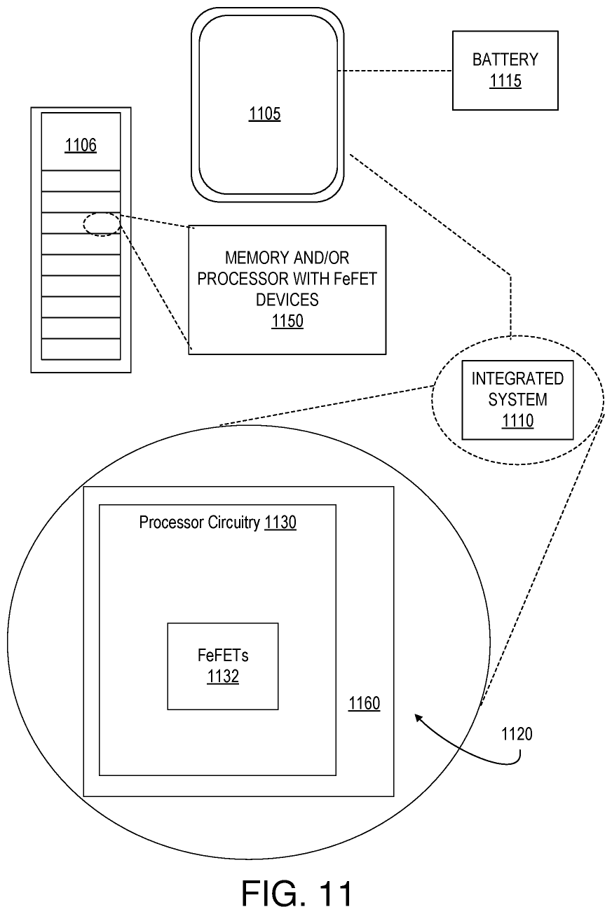

FIG. 11 illustrates a mobile computing platform 1105 and a data server computing platform 1106 employing an IC including FeFETs as described herein. The server platform 1106 may be any commercial server, for example including any number of high-performance computing platforms disposed within a rack and networked together for electronic data processing, which in the exemplary embodiment includes a microprocessor 1150 including FeFETs as described herein.

The mobile computing platform 1105 may be any portable device configured for each of electronic data display, electronic data processing, wireless electronic data transmission, or the like. For example, the mobile computing platform 1105 may be any of a tablet, a smart phone, laptop computer, etc., and may include a display screen (e.g., a capacitive, inductive, resistive, or optical touchscreen), a chip-level or package-level integrated system 1110, and a battery 1115. At least one IC of chip-level or package-level integrated system 1110 includes FeFETs as described herein. In the example shown in expanded view 1120, integrated system 1110 includes microprocessor circuitry 1130 including FeFETs 1132 as described herein.

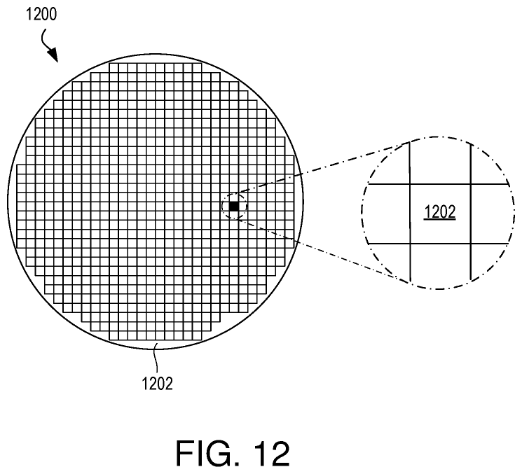

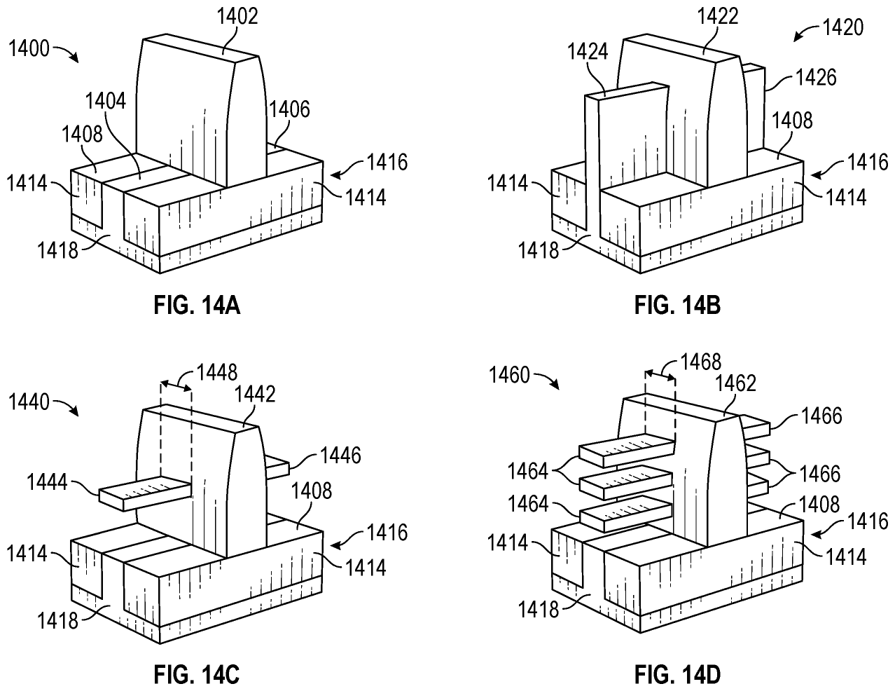

FIG. 12 is a top view of a wafer 1200 and dies 1202 wherein individual dies may include FeFETs as described herein. The wafer 1200 may be composed of semiconductor material and may include one or more dies 1202 having integrated circuit structures formed on a surface of the wafer 1200. The individual dies 1202 may be a repeating unit of an integrated circuit product that includes any suitable integrated circuit. After the fabrication of the semiconductor product is complete, the wafer 1200 may undergo a singulation process in which the dies 1202 are separated from one another to provide discrete “chips” of the integrated circuit product. The die 1202 may include one or more transistors (e.g., some of the transistors 1140 of FIG. 11, discussed below and/or FeFETS as described herein), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, OTP RAM, etc.), a logic device (e.g., an AND, OR, NAND, or NOR gate), or any other suitable circuit element. Multiple ones of these devices may be combined on a single die 1202. For example, a memory array formed by multiple memory devices may be formed on a same die 1202 as a processor unit (e.g., the processor unit 1402 of FIG. 14) or other logic that is configured to store information in the memory devices or execute instructions stored in the memory array.

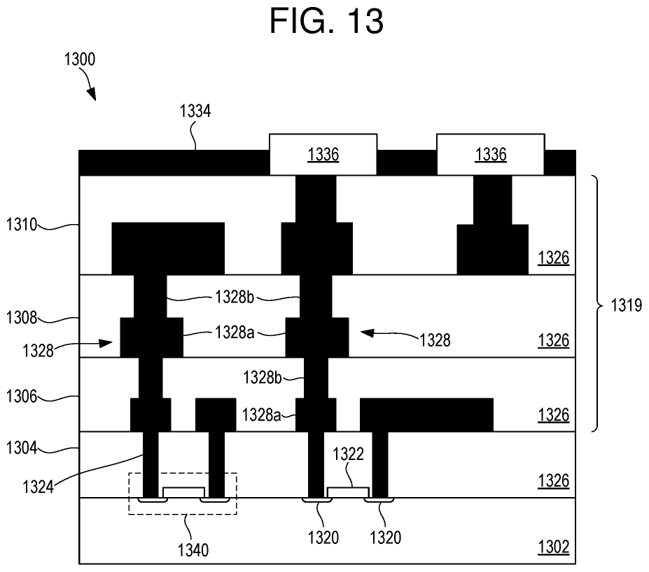

FIG. 13 is a cross-sectional side view of an integrated circuit device 1300 that may include FeFETs as described herein. One or more of the integrated circuit devices 1300 may be included in one or more dies 1202 (FIG. 12). The integrated circuit device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit device 1300 may be used. The die substrate 1302 may be part of a singulated die (e.g., the dies 1202 of FIG. 12) or a wafer (e.g., the wafer 1200 of FIG. 12).

The integrated circuit device 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors. Transistors 1340 may also include FeFETs as described herein.

FIGS. 14A-14D are simplified perspective views of example planar, FinFET, gate-all-around, and stacked gate-all-around transistors. The transistors illustrated in FIGS. 14A-14D are formed on a substrate 1416 having a surface 1408. Isolation regions 1414 separate the source and drain regions of the transistors from other transistors and from a bulk region 1418 of the substrate 1416.

FIG. 14A is a perspective view of an example planar transistor 1400 comprising a gate 1402 that controls current flow between a source region 1404 and a drain region 1406. The transistor 1400 is planar in that the source region 1404 and the drain region 1406 are planar with respect to the substrate surface 1408.

FIG. 14B is a perspective view of an example FinFET transistor 1420 comprising a gate 1422 that controls current flow between a source region 1424 and a drain region 1426. The transistor 1420 is non-planar in that the source region 1424 and the drain region 1426 comprise “fins” that extend upwards from the substrate surface 1428. As the gate 1422 encompasses three sides of the semiconductor fin that extends from the source region 1424 to the drain region 1426, the transistor 1420 can be considered a tri-gate transistor. FIG. 14B illustrates one S/D fin extending through the gate 1422, but multiple S/D fins can extend through the gate of a FinFET transistor.

FIG. 14C is a perspective view of a gate-all-around (GAA) transistor 1440 comprising a gate 1442 that controls current flow between a source region 1444 and a drain region 1446. The transistor 1440 is non-planar in that the source region 1444 and the drain region 1446 are elevated from the substrate surface 1428.

FIG. 14D is a perspective view of a GAA transistor 1460 comprising a gate 1462 that controls current flow between multiple elevated source regions 1464 and multiple elevated drain regions 1466. The transistor 1460 is a stacked GAA transistor as the gate controls the flow of current between multiple elevated S/D regions stacked on top of each other. The transistors 1440 and 1460 are considered gate-all-around transistors as the gates encompass all sides of the semiconductor portions that extends from the source regions to the drain regions. The transistors 1440 and 1460 can alternatively be referred to as nanowire, nanosheet, or nanoribbon transistors depending on the width (e.g., widths 1448 and 1468 of transistors 1440 and 1460, respectively) of the semiconductor portions extending through the gate.

Returning to FIG. 13, a transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit device 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuit devices having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit device 1300 (e.g., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit device 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit device 1300 with another component (e.g., a printed circuit board). The integrated circuit device 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit device 1300 is a double-sided die, the integrated circuit device 1300 may include another metallization stack (not shown) on the opposite side of the device layer(s) 1304. This metallization stack may include multiple interconnect layers as discussed above with reference to the interconnect layers 1306-1310, to provide conductive pathways (e.g., including conductive lines and vias) between the device layer(s) 1304 and additional conductive contacts (not shown) on the opposite side of the integrated circuit device 1300 from the conductive contacts 1336.

In other embodiments in which the integrated circuit device 1300 is a double-sided die, the integrated circuit device 1300 may include one or more through silicon vias (TSVs) through the die substrate 1302; these TSVs may make contact with the device layer(s) 1304, and may provide conductive pathways between the device layer(s) 1304 and additional conductive contacts (not shown) on the opposite side of the integrated circuit device 1300 from the conductive contacts 1336. In some embodiments, TSVs extending through the substrate can be used for routing power and ground signals from conductive contacts on the opposite side of the integrated circuit device 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuit devices 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

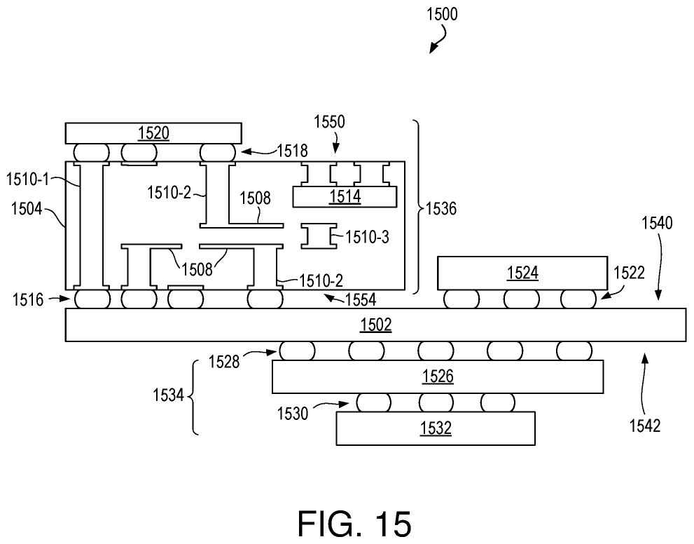

FIG. 15 is a cross-sectional side view of an integrated circuit device assembly 1500. The integrated circuit device assembly 1500 includes a number of components disposed on a circuit board 1502 (which may be a motherboard, system board, mainboard, etc.). The integrated circuit device assembly 1500 includes components disposed on a first face 1540 of the circuit board 1502 and an opposing second face 1542 of the circuit board 1502; generally, components may be disposed on one or both faces 1540 and 1542.

In some embodiments, the circuit board 1502 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate. The integrated circuit device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1536 may include an integrated circuit component 1520 coupled to an interposer 1504 by coupling components 1518. The coupling components 1518 may take any suitable form for the application, such as the forms discussed above with reference to the coupling components 1516. Although a single integrated circuit component 1520 is shown in FIG. 15, multiple integrated circuit components may be coupled to the interposer 1504; indeed, additional interposers may be coupled to the interposer 1504. The interposer 1504 may provide an intervening substrate used to bridge the circuit board 1502 and the integrated circuit component 1520.

The integrated circuit component 1520 may be a packaged or unpacked integrated circuit product that includes one or more integrated circuit dies (e.g., the die 1202 of FIG. 12, the integrated circuit device 1100 of FIG. 11, etc.) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1520, a single monolithic integrated circuit die comprises solder bumps attached to contacts on the die. The solder bumps allow the die to be directly attached to the interposer 1504. The integrated circuit component 1520 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1520 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1520 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1504 may spread connections to a wider pitch or reroute a connection to a different connection. For example, the interposer 1504 may couple the integrated circuit component 1520 to a set of ball grid array (BGA) conductive contacts of the coupling components 1516 for coupling to the circuit board 1502. In the embodiment illustrated in FIG. 15, the integrated circuit component 1520 and the circuit board 1502 are attached to opposing sides of the interposer 1504; in other embodiments, the integrated circuit component 1520 and the circuit board 1502 may be attached to a same side of the interposer 1504. In some embodiments, three or more components may be interconnected by way of the interposer 1504.

In some embodiments, the interposer 1504 may be formed as a PCB, including multiple metal layers separated from one another by layers of dielectric material and interconnected by electrically conductive vias. In some embodiments, the interposer 1504 may be formed of an epoxy resin, a fiberglass-reinforced epoxy resin, an epoxy resin with inorganic fillers, a ceramic material, or a polymer material such as polyimide. In some embodiments, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through hole vias 1510-1 (that extend from a first face 1550 of the interposer 1504 to a second face 1554 of the interposer 1504), blind vias 1510-2 (that extend from the first or second faces 1550 or 1554 of the interposer 1504 to an internal metal layer), and buried vias 1510-3 (that connect internal metal layers).

In some embodiments, the interposer 1504 can comprise a silicon interposer. Through silicon vias (TSV) extending through the silicon interposer can connect connections on a first face of a silicon interposer to an opposing second face of the silicon interposer. In some embodiments, an interposer 1504 comprising a silicon interposer can further comprise one or more routing layers to route connections on a first face of the interposer 1504 to an opposing second face of the interposer 1504.

The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The integrated circuit device assembly 1500 may include an integrated circuit component 1524 coupled to the first face 1540 of the circuit board 1502 by coupling components 1522. The coupling components 1522 may take the form of any of the embodiments discussed above with reference to the coupling components 1516, and the integrated circuit component 1524 may take the form of any of the embodiments discussed above with reference to the integrated circuit component 1520.

The integrated circuit device assembly 1500 illustrated in FIG. 15 includes a package-on-package structure 1534 coupled to the second face 1542 of the circuit board 1502 by coupling components 1528. The package-on-package structure 1534 may include an integrated circuit component 1526 and an integrated circuit component 1532 coupled together by coupling components 1530 such that the integrated circuit component 1526 is disposed between the circuit board 1502 and the integrated circuit component 1532. The coupling components 1528 and 1530 may take the form of any of the embodiments of the coupling components 1516 discussed above, and the integrated circuit components 1526 and 1532 may take the form of any of the embodiments of the integrated circuit component 1520 discussed above. The package-on-package structure 1534 may be configured in accordance with any of the package-on-package structures known in the art.

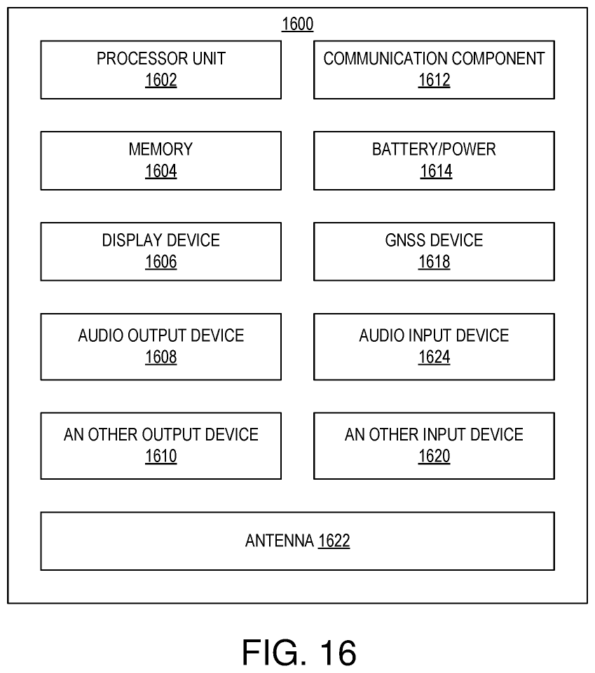

FIG. 16 is a block diagram of an example electrical device 1600 that may include FeFETs as disclosed herein. For example, any suitable ones of the components of the electrical device 1600 may include one or more of the integrated circuit device assemblies 1500, integrated circuit components 1520, integrated circuit devices 1100, or integrated circuit dies 1202 disclosed herein. A number of components are illustrated in FIG. 16 as included in the electrical device 1600, but any one or more of these components may be omitted or duplicated, as suitable for the application. In some embodiments, some or all of the components included in the electrical device 1600 may be attached to one or more motherboards mainboards, or system boards. In some embodiments, one or more of these components are fabricated onto a single system-on-a-chip (SoC) die.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1600 can comprise one or more processor units 1602 that are heterogeneous or asymmetric to another processor unit 1602 in the electrical device 1600. There can be a variety of differences between the processing units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include another output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include another input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of embodiments has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first gate and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

In embodiments, the phrase “A is located on B” means that at least a part of A is in direct physical contact or indirect physical contact (having one or more other features between A and B) with at least a part of B.

In the instant description, “A is adjacent to B” means that at least part of A is in direct physical contact with at least a part of B.

In the instant description, “B is between A and C” means that at least part of B is in or along a space separating A and C and that the at least part of B is in direct or indirect physical contact with A and C.

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “according to some embodiments,” “in accordance with embodiments,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features.

Example 1 includes an apparatus, comprising a field effect transistor comprising a ferroelectric material; a channel material on the ferroelectric material, the channel material comprising a transition metal and a chalcogen; and a source and a drain coupled to the channel material, the source and drain comprising a conductive material.

Example 2 includes the subject matter of Example 1, and wherein the channel material comprises a 2D transition metal dichalcogenide.

Example 3 includes the subject matter of any of Examples 1 and 2, and wherein the ferroelectric material comprises Barium, Titanium, and Oxygen.

Example 4 includes the subject matter of any of Examples 1-3, and wherein the channel material comprises WSe2.

Example 5 includes the subject matter of any of Examples 1-4, and wherein the channel material comprises a P-type channel.

Example 6 includes the subject matter of any of Examples 1-5, and further including an oxide on the channel material, and wherein the channel material comprises an N-type channel.

Example 7 includes the subject matter of any of Examples 1-6, and wherein the oxide on the channel material comprises Aluminum and Oxygen.

Example 8 includes the subject matter of any of Examples 1-7, and further including an oxide between the ferroelectric material and the source and drain.

Example 9 includes the subject matter of any of Examples 1-8, and wherein the ferroelectric material is on a conductive material.

Example 10 includes the subject matter of any of Examples 1-9, and further including an integrated circuit die comprising the field effect transistor.

Example 11 includes the subject matter of any of Examples 1-10, and further including a circuit board coupled to the integrated circuit die.

Example 12 includes the subject matter of any of Examples 1-11, and further comprising at least one of a network interface, battery, or memory coupled to the integrated circuit die.

Example 13 includes an apparatus comprising a complementary metal oxide semiconductor circuit comprising a P-type field effect transistor (FET) comprising a ferroelectric material; and a channel comprising a transition metal and a chalcogen; and an N-type FET comprising the ferroelectric material; and a channel comprising the transition metal and the chalcogen.

Example 14 includes the subject matter of Example 13, and wherein the P-type FET and N-type FET comprise respective drains coupled together and respective gates coupled together.

Example 15 includes the subject matter of any of Examples 13 and 14, and wherein the circuit is operable to function as either a memory element or a logic element dependent on one or more bias voltages applied to the circuit.

Example 16 includes the subject matter of any of Examples 13-15, and wherein the ferroelectric material comprises Barium, Titanium, and Oxygen.

Example 17 includes the subject matter of any of Examples 13-16, and wherein the channels comprise a 2D transition metal dichalcogenide.

Example 18 includes the subject matter of any of Examples 13-17, and wherein the channels comprise WSe2.

Example 19 includes the subject matter of any of Examples 13-18, and further including an oxide on the channel of the N-type FET.

Example 20 includes the subject matter of any of Examples 13-19, and wherein the oxide on the channel of the N-type FET comprises Aluminum and Oxygen.

Example 21 includes the subject matter of any of Examples 13-20, and further including an oxide between the ferroelectric material and the source and drain.

Example 22 includes the subject matter of any of Examples 13-21, and wherein the ferroelectric material is on a conductive material.

Example 23 includes the subject matter of any of Examples 13-22, and further including an integrated circuit die comprising the complementary metal oxide semiconductor circuit.

Example 24 includes the subject matter of any of Examples 13-23, and further including a circuit board coupled to the integrated circuit die.

Example 25 includes the subject matter of any of Examples 13-24, further comprising at least one of a network interface, battery, or memory coupled to the integrated circuit die.

Example 26 includes a method comprising forming a substrate comprising a ferroelectric material; forming a channel material on the substrate, the channel material comprising a metal and a chalcogen; and forming a plurality of field effect transistors, respective field effect transistors comprising portions of the ferroelectric material and portions of the channel material.

Example 27 includes the subject matter of Example 26, and wherein forming the channel material on the substrate comprises transferring the channel material from an additional substrate to the substrate.

Example 28 includes the subject matter of any of Examples 26 and 27, and further including applying a surface treatment to the substrate prior to transferring the channel material to the substrate.

Example 29 includes the subject matter of any of Examples 26-28, and wherein the ferroelectric material comprises Barium, Titanium, and Oxygen.

Example 30 includes the subject matter of any of Examples 26-29, and wherein the channel material comprises a 2D transition metal dichalcogenide.

Example 31 includes the subject matter of any of Examples 26-30, and wherein the channel material comprises WSe2.

Example 32 includes the subject matter of any of Examples 26-31, and wherein the channel material comprises a P-type channel.

Example 33 includes the subject matter of any of Examples 26-32, and further including forming an oxide on the channel material, and wherein the channel material comprises an N-type channel.

Example 34 includes the subject matter of any of Examples 26-33, and wherein the oxide on the channel material comprises Aluminum and Oxygen.

Example 35 includes the subject matter of any of Examples 26-34, and further including forming an oxide between the ferroelectric material and the source and drain.

Example 36 includes the subject matter of any of Examples 26-35, and wherein the ferroelectric material is formed on a conductive material.

Example 37 includes the subject matter of any of Examples 26-36, and further including forming an integrated circuit die comprising the plurality of field effect transistors.

Example 38 includes the subject matter of any of Examples 26-37, and further including coupling a circuit board to the integrated circuit die.

Example 39 includes the subject matter of any of Examples 26-38, and further including coupling at least one of a network interface, battery, or coupled to the integrated circuit die.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

What is claimed is:

1. An apparatus, comprising:
a field effect transistor comprising:
a ferroelectric material;
a channel material on the ferroelectric material, the channel material comprising a transition metal and a chalcogen; and
a source and a drain coupled to the channel material, the source and drain comprising a conductive material.

2. The apparatus of claim 1, wherein the channel material comprises a 2D transition metal dichalcogenide.

3. The apparatus of claim 1, wherein the ferroelectric material comprises Barium, Titanium, and Oxygen.

4. The apparatus of claim 1, wherein the channel material comprises WSe₂.

5. The apparatus of claim 1, wherein the channel material comprises a P-type channel.

6. The apparatus of claim 1, further comprising an oxide on the channel material, and wherein the channel material comprises an N-type channel.

7. The apparatus of claim 6, wherein the oxide on the channel material comprises Aluminum and Oxygen.

8. The apparatus of claim 1, further comprising an oxide between the ferroelectric material and the source and drain.

9. The apparatus of claim 1, wherein the ferroelectric material is on a conductive material.

10. The apparatus of claim 1, further comprising an integrated circuit die comprising the field effect transistor.

11. The apparatus of claim 10, further comprising a circuit board coupled to the integrated circuit die.

12. The apparatus of claim 10, further comprising at least one of a network interface, battery, or memory coupled to the integrated circuit die.

13. An apparatus comprising:
a complementary metal oxide semiconductor circuit comprising:
a P-type field effect transistor (FET) comprising:
a ferroelectric material; and
a channel comprising a transition metal and a chalcogen; and
an N-type FET comprising:
the ferroelectric material; and
a channel comprising the transition metal and the chalcogen.

14. The apparatus of claim 13, wherein the P-type FET and N-type FET comprise respective drains coupled together and respective gates coupled together.

15. The apparatus of claim 13, wherein the circuit is operable to function as either a memory element or a logic element dependent on one or more bias voltages applied to the circuit.

16. The apparatus of claim 13, wherein the ferroelectric material comprises Barium, Titanium, and Oxygen.

17. A method comprising:
forming a substrate comprising a ferroelectric material;
forming a channel material on the substrate, the channel material comprising a metal and a chalcogen; and
forming a plurality of field effect transistors, respective field effect transistors comprising portions of the ferroelectric material and portions of the channel material.

18. The method of claim 17, wherein forming the channel material on the substrate comprises transferring the channel material from an additional substrate to the substrate.

19. The method of claim 18, further comprising applying a surface treatment to the substrate prior to transferring the channel material to the substrate.

20. The method of claim 17, wherein the ferroelectric material comprises Barium, Titanium, and Oxygen.
